(19) United States
(12) Patent Application Publication
(10) Pub. No.: US 2007/0023769 A1
(43) Pub. Date: Feb. 1, 2007

(54) Led lighting source and led lighting apparatus

(76) Inventors: Keiji Nishimoto, Takatsuki-shi (JP); Noriyasu Tanimoto, Takatsuki-shi (JP); Masanori Shimizu, Kyotanabe-shi (JP); Hideo Nagai, Takatsuki-shi (JP); Takeshi Saito, Nishinomiya-shi (JP)

Correspondence Address: SNELL & WILMER L.L.P., 600 ANTON BOULEVARD, SUITE 1400, COSTA MESA, CA, 92626, US

(21) Appl. No.: 10/569,360

(22) PCT Filed: Sep. 7, 2004
(86) PCT No.: PCT/JP04/13290

§ 371 Date: Feb. 24, 2006

(30) Foreign Application Priority Data
Sep. 16, 2003 (JP) 2003-323575

(51) Int. Cl. H01L 33/00

(52) U.S. Cl. 257/88

(57) ABSTRACT

An LED lighting source preventing heat deterioration and improving luminous efficiency includes a mounting substrate having a wiring pattern on a first main surface thereof and a plurality of LED bare chips, each composed of a first semiconductor layer and a second semiconductor layer having respectively different conductivity, an active layer disposed therebetween, and a metal electrode on the first semiconductor layer and substantially equal in area thereto, and each LED bare chip being joined to the wiring pattern according to flip chip mounting of the metal electrode to form a junction between the wiring pattern and the metal electrode. Each junction is formed so that an area thereof is at least 20% of the area of the metal electrode. Thermal resistance from the active layers through to a second main surface of the mounting substrate, which is a back surface thereof, is set to 3.0 9C./W or lower.

### TECHNICAL FIELD

The present invention relates to an LED module used in an LED lighting source or an LED lighting apparatus, and in particular to a technique for improving thermal dissipation properties.

### BACKGROUND ART

LED lighting sources which use LEDs (Light Emitting Diodes) are receiving attention as the next generation of light sources. Unlike general, conventional light sources, LEDs have the advantage of having a long life, as well as being able to be made extremely thin and compact. For this reason, LEDs are superior in that they present relatively few restrictions in terms of installation position, and therefore high expectations are held that LEDs will be able to be used for a wide range of applications.

As one specific example of an LED lighting source, an LED module has been developed in which plurality of LED bare chips are mounted densely on a substrate, and the surface of the LED bare chips is covered with transparent resin. Such an LED module is disclosed in Japanese Patent Application Publication No. 2003-124528.

LED lighting apparatus of various shapes and light outputs can be achieved by using one or multiple LED modules having the described structure, with each LED module being removably held by a socket or connector and power being supplied thereto.

However, since the aforementioned LED module uses LED bare chips as the light source, a relatively large amount of power must be supplied thereto. Specifically, in order to increase the luminous flux of each LED bare chip as much as possible, it is necessary to supply current to each LED bare chip that is greater than current in ordinary use other than lighting (for example, for light emission display). As one example, if the LED bare chips have a 0.3 mm square, and the current in ordinary use is approximate 20 mA, the current density of the active layer is approximately 222.2 mA/mm², and to increase luminous flux, if overcurrent (maximum current) is approximately 40 mA, current density in the active layer is approximately 444.4 mA/mm².

While supplying a large current as described above achieves a high light output from the LED bare chips during driving, the temperature of the LED bare chips mounted on the substrate (also called junction temperature) rises considerably. Generally, one property of LED bare chips is that being placed in a state of high temperature has a great effect on life span. For example, the life span of an LED lighting apparatus in which LED bare chips are used is thought to be reduced by half if, at room temperature, the temperature of the LED bare chips increases by 10° C. Furthermore, being in a high temperature state causes a problems of thermal deterioration and reduces the luminous efficiency (light usage efficiency).

For these reasons, in order to maintain the luminous efficiency of light sources of LED lighting such as LED modules, heat must be dissipated such that the mounted LED bare chips do not reach a state of excessively high temperature.

Furthermore, in LED lighting apparatuses that use LED modules, heat that occurs during driving is intended to be dissipated outside mainly from the back surface of the LED modules. For this reason, in LED lighting apparat uses, a structure in which a heatsink is provided in close thermal contact with the back surface of each LED module is employed. However, the heat dissipating effect of such heatsinks is presently not being used to its full potential, and there is still much room for improvement.

### DISCLOSURE OF THE INVENTION

In view of the stated problems, the object of the present invention is to provide an LED lighting source, such as an LED module, that has superior performance by preventing deterioration of LED bare chips and improving luminous efficiency, and an LED lighting apparatus that uses the LED lighting source.

In order to solve the stated problems, the present invention is an LED lighting source including: a mounting substrate having a wiring pattern on a first main surface thereof; and a plurality of LED bare chips, each composed of a first semiconductor layer and a second semiconductor layer that have respectively different conductivity, an active layer disposed between the first and second semiconductor layers, and a metal electrode disposed on the first semiconductor layer and being substantially equal in area to the first semiconductor layer, and each LED bare chip being joined to the wiring pattern according to flip chip mounting of the metal electrode to form a junction between the wiring pattern and the metal electrode, wherein each junction is formed so that an area thereof is at least 20% of the area of the metal electrode, and thermal resistance from the active layers through to a second main surface of the mounting substrate, which is a back surface thereof, is set to 3.0° C./W or lower.

According to the LED lighting source of the present invention having the stated structure, the junction area of the wiring and the metal electrode, which is substantially equal in size to the area of the first semiconductor layer of the LED bare chip, is set so as to be at least 20% of the first semiconductor layer that opposes the wiring. In addition, the thermal resistance from the active layer through to back surface of the mounting substrate of the LED bare chip is set so as to be no more than 3.0° C./W. According to the stated structure, thermal conductivity from the active layer to the substrate side is improved, the temperature of the LED bare chip during driving is kept to 80° C. or lower, and the excessive temperature rises can be avoided. As a result, thermal deterioration of the LED bare chip is prevented, and the LED lighting source can be driven favorably, maintaining luminous efficiency.

Here, at least the metal electrodes and the wiring pattern may be joined according to one of a gold-gold junction, a gold-aluminium junction, and a gold-tin junction.

Furthermore, each junction may be made up of two or more bumps.

Specifically, each junction may be made up of two or more bumps that each have a diameter of at least 100 μm, or three or more bumps that each have a diameter of at least 80 μm.

In such an LED bare chip, it is preferable that current density of the active layer of each LED bare chip during driving is in a range of 250 mA/mm² to 660 mA/mm² inclusive.

Furthermore, the mounting substrate may be composed of an insulation layer and a metal layer, the first main surface on which the wiring pattern is disposed being a main surface of the insulation layer, and the second main surface of the mounting substrate, which is an opposite surface to the surface on which the wiring pattern is disposed, being a surface of the metal layer.

Here, the mounting substrate may include an insulation layer that is composed of a composite material that includes an inorganic filler and a resin composite.

Alternatively, the mounting layer may include an insulation layer that is composed of a ceramic material.

Furthermore, the mounting substrate may be composed of a ceramic material. In this case, the ceramic material may include at least one of AlN, Al₂O₃, and SiO₂.

Furthermore, the present invention is an LED lighting apparatus including the stated LED lighting source, wherein the LED lighting apparatus includes a heatsink that is provided in close thermal contact with the back surface of the mounting substrate, and that has a thermal resistance of no less than 1.0° C./W and no greater than 4.° C./W.

Furthermore, the present invention is an LED lighting apparatus including the stated LED lighting source, wherein the LED lighting apparatus includes a heatsink that is provided in close thermal contact with the back surface of the mounting substrate, and that has an enveloping volume of 100 cm³ to 820 cm³, inclusive.

Note that the heatsink may be composed of at least one material chosen form the group consisting of Al, Cu, W, Mo, Si, AlN, and SiC.

In the present invention, even if the LED bare chip growth substrate has a conventional structure, such as sapphire, SiC, GaN or AlN, since the heat from the active layer is directly dissipated through the first semiconductor layer, the LED bare chip temperature can be adjusted simply by setting the junction area with the wiring. This is advantageous in that the present invention can be realized relatively simply using a conventional manufacturing method. The fold bumps and metal have high heat dissipating properties, and therefore are advantageous in adjusting thermal resistance.

Furthermore, in the LED lighting apparatus of the present invention that used the LED lighting source with the stated structure, heat from the LED lighting source is effectively dissipated due to a heatsink having a thermal resistance of 4.0° C./W or lower being provided in close thermal contact with the back surface of the substrate of the LED lighting source. By using heatsink with such heat dissipating characteristics, the temperature of the LED bare chips during driving can be kept to 80° C. or below. This enables luminous efficiency to be maintained while prevention heat deterioration of the LED bare chips, and an LED lighting apparatus with favorable performance to be realized.

### BRIEF DESCRIPTION OF THE DRAWINGS

FIG. 1 shows the structure of an LED card in a first embodiment;

FIGS. 2A and 2B show examples of a substrate wiring patterns;

FIGS. 3A and 3B show the substrate circuit structures;

FIG. 4 shows the structure an LED device and its surroundings;

FIG. 5 shows the structure of an LED device and its surroundings;

FIG. 6 shows an LED bare chip mounting structure;

FIG. 7 is a graph showing the relationship between ambient temperature and forward current characteristics of a general LED bare chip;

FIG. 8 is a graph showing the relationship between bare chip temperature and thermal resistance;

FIG. 9 is a graph showing the relationship between the p electrode area occupied by the junction area (G1 and G2 spot area) and the junction temperature Tj;

FIGS. 10A and 10B show the structure of an LED lighting apparatus of a second embodiment;

FIGS. 11A and 11B are cross sectional diagrams showing the structure of the LED lighting apparatus;

FIG. 12 is a graph showing the relationship between bare chip temperature and heatsink thermal resistance;

FIG. 13 is a graph showing the relationship between bare chip temperature and heatsink enveloping volume;

FIG. 14 is a graph showing the relationship between bare chip temperature and heatsink area;

FIG. 15 is a graph showing the relationship between bare chip temperature and heatsink weight;

FIGS. 16A and 16B show structures of LED lighting apparatuses as variations;

FIGS. 17A, 17B and 17C show examples of structures of heatsinks as variations;

FIG. 18 shows an alternative structure of an LED card; and

FIG. 19 shows another alternative structure of an LED card.

### BEST MODE FOR CARRYING OUT THE INVENTION

<First Embodiment>

1-1. Overall Structure of Card-Type LED Module

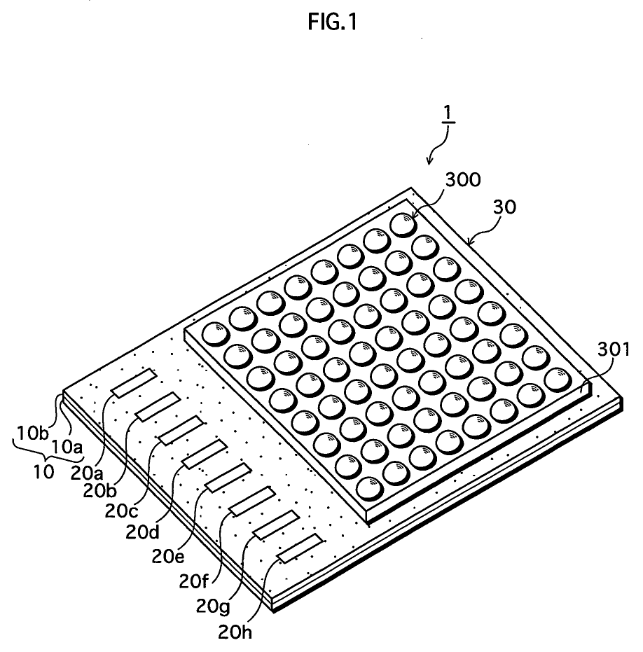

FIG. 1 is a perspective view showing the overall structure of a card-type LED module 1 (hereinafter called “LED card 1”) of the first embodiment.

The LED card 1 is roughly composed of a substrate 10, an LED light source unit 30 formed on the surface of the substrate 10 (the surface of an insulation layer 10b), and power supply terminals 20a to 20h.

The substrate 10 is made of a highly thermally distributive metal composite (here, a aluminium composite) and is composed of a circuit formation unit (insulation layer) 10b and a metal layer 10a. One example of the size of the substrate 10 is 28.5 mm (depth) by 23.5 mm (width) by 1.2 mm (height). The circuit formation unit 10b is a 0.2 mm-thick mounting surface made of a mixture of a resin composite and an inorganic filler. The metal layer 10a is aluminium or the like with a thickness of 1.0 mm. The overall thickness of the substrate 10 is preferably at least 0.7 mm from a point of view of heat dissipation characteristics and mechanical strength during driving, and no more than 2.0 mm for ease of cutting the substrate. Note that the overall shape of the substrate 10 may be varied appropriately according to conditions such as the number of LED devices 300 to be mounted, and the substrate 10 is not limited to the described size.

The inorganic filler is preferably at least one type selected from the group consisting of Al₂O₃, MgO, BN, SiO₂, SiC, Si₃N₄, and AlN. Furthermore, to achieve a high filling rate and heat conductivity properties, it is preferable that the particles of the inorganic filler are grain-shaped, and particularly preferable that the particles are spherical. The resin composite preferably includes at least one type selected from the group consisting of epoxy resin, phenol resin, and cyanate resin. In addition, the resin composite is preferably formed from a mixture of 70% to 95% of the inorganic filler and 5% to 30% of the resin composite.

Note that a ceramic material may be used for the insulation layer 10b. If a ceramic material is used, it is preferable that the ceramic material includes at least one type from the group consisting of MgO, CaO, SrO, BaO, Al₂O₃, SiO₂, ZnO, TiO₂, NiO, Nb₂O₃, CuO, MnO, and WO₃.

The metal layer 10a may be fabricated from aluminium, copper, iron, stainless steel, or an alloy of any of these. In terms of heat dissipating properties, copper, aluminium, iron and stainless steel, in the stated order, are superior. On the other hand, in terms of heat expansion rate, iron, stainless steel, copper, and aluminium, in the stated order, are superior. Furthermore, in terms of ease of use, such as in rust prevention processing, an aluminium material is preferable, and in terms of avoiding reliability deterioration caused by heat expansion, iron or stainless steel is preferable. In this way, an appropriate material may be selected according to needs. Furthermore, by subjecting the surface of the metal layer 10a to insulation processing, short circuits caused by the metal layer 10a touching the wiring 200 and 201 or the like can be prevented. Examples of such insulation processing include electrolytic polishing, andodizing, electroless plating, and electrodeposition.

Note that the back surface of the metal layer 10a is flat in order to achieve a high heat conductivity rate, under the assumption that heat dissipating means such as a heatsink will be provided in close thermal contact with the back surface.

Furthermore, although the substrate 10 is described as having a structure in which the metal layer 10a and the insulation layer 10b are layered together, a ceramic substrate may instead be used in the present invention. In such as case, it is preferable to use a material that includes at least one of AlN, Al₂O₃, and SiO₂ which have relatively high thermal conductivity.

1-2. Substrate Wiring

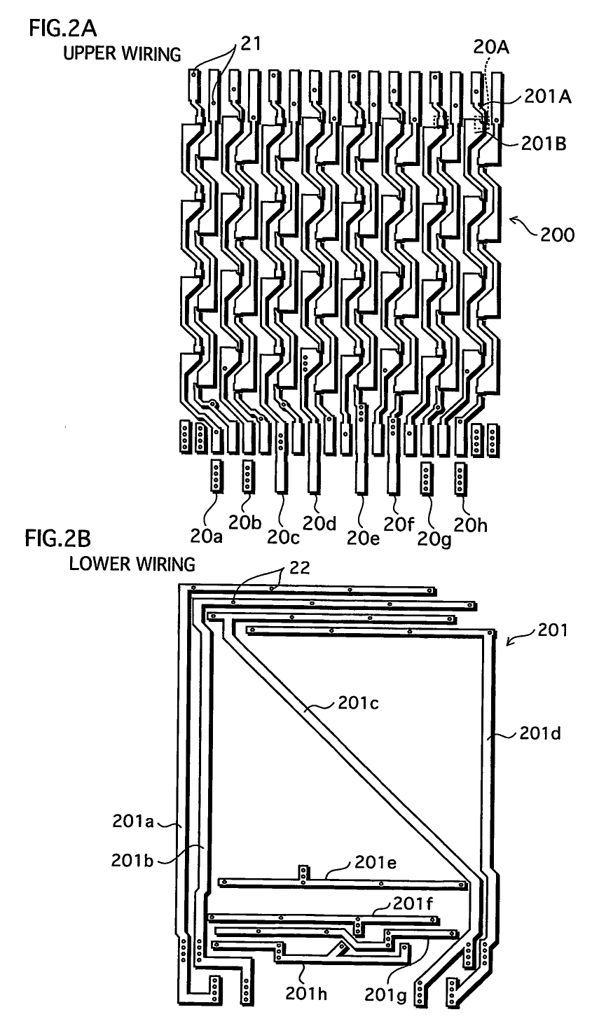

Upper layer wiring 200 of Cu foil in a pattern shown as shown as an example in FIG. 2A is formed on the surface of the insulation layer 10b. The surface of this upper layer wiring 200 is plated with Ni—Au. In the pattern in the drawing, patterns 201A, 201B, and so on, which are isolated from and independent of each other, are provided successively, and an LED bare chip 2 is mounted according to flip chip junction in each of opposing parts between each two adjacent patterns (for example, 201A and 201B) in the lengthwise direction of the substrate (the vertical direction in the drawing). An area 20A in FIG. 2A indicates a specific LED bare chip mounting area.

Furthermore, the power supply terminals 20a to 20h are disposed at one end of the upper layer wiring 200. The power supply terminals 20a to 20h are connected to external terminals, and are for supplying power to the LED to 300. It is preferable to use a socket or a connecter to hold the LED 1 when the power supply terminals 20a to 20h are connected to the external terminals. Here, “socket” and “connector” refer to a material or component in which the LED card 1 of the present embodiment is able to be detachably mounted in order to achieve an electrical connection. The LED card 1 can be driven with use of a conventional system for electrical connection if the size of the LED card 1 is made to suit specifications of a socket or connector for an existing memory card or the like.

The number of the power supply terminals 20a to 20h and the positional relationship thereof on the insulation layer 10b are not limited to those described, however the pitch of adjacent terminals should preferably be maintained at least 0.8 mm in order to prevent short circuits.

Lower wiring 201 made of Cu foil in the pattern shown in FIG. 2B is provided internally in the insulation layer 10b. The lower wiring 201 has linear patterns 201a to 201h and is arranged so as to appropriately connect the upper wiring 200. The upper wiring 200 and the lower wiring 201 are mutually connected inside the insulation layer 10b through connection vias 21 and 22.

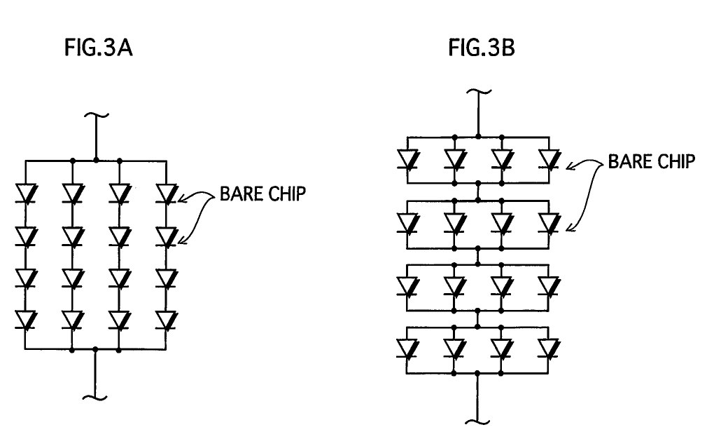

According to this kind of wiring 200 and 201, in the first embodiment, a series-parallel circuit made up of LED to 300 shown in FIG. 3A is formed. Note that the structure of the circuit is not limited to that described, and may use numerous parallel connection of LED to 300 as shown in FIG. 3B.

1-3. Structure of the LED Light Source Unit

An LED light source unit 30 shown in FIG. 1 is the principal compositional device of the LED card 1, and is mounted with high density as a lighting-use light source, not as a conventional display-use light source or the like. As one specific example, 8 by 8 (64 in total) LED to 300 of a diameter of 2 mm at set intervals on the main surface of the insulation layer 10b, arranged in a square shape having a 20 mm square size. As one example of specifications, a forward direction current of 40 mA and a forward direction voltage of 120 V achieve a luminous output of 1201 m during driving at a room temperature of 25° C. (measurement conditions for light output of general lamps for lighting determined by JIS standard). The overall height of the LED card 1 to the LED light source unit 30 is 3 mm.

Note that the number of LED to 300 and the pattern in which they are arranged are not limited to the described example.

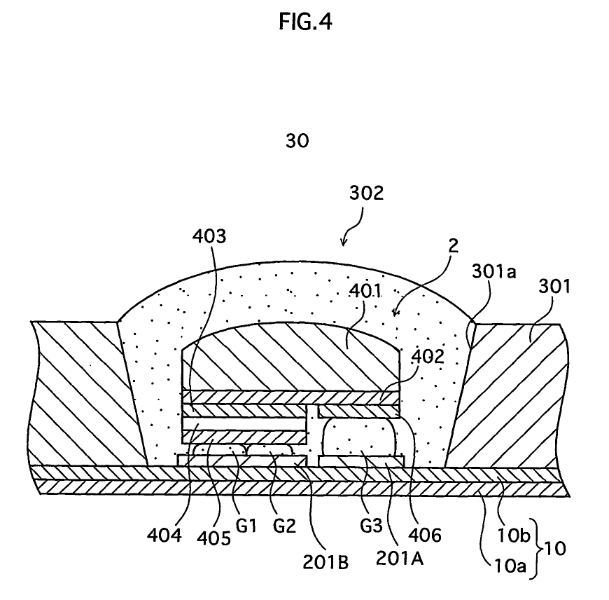

The structure of the LED device 300 and its surrounds is as shown in an enlarged cross-sectional view in FIG. 4.

First, an aperture is formed in an aluminium optical reflecting plate 301 that is to act as a frame, so as to have a diameter of 2 mm and a conical reflection surface 301a. The optical reflecting plate 301 is then laminated on the surface of the insulation layer 10b.

The LED bare chips 2 are formed, as one example, in a square shape having a 0.32 mm square. Each LED bare chip 2 has a structure in which on a lower surface of a device substrate 401 that is sapphire a GaN second semiconductor layer (called an n-type semiconductor layer) 402, an active layer 403, a first semiconductor layer (called a p-type semiconductor layer) 404 are layered downward in the stated order. Furthermore, an n-type semiconductor layer electrode (called an n electrode) 406 and a p-type semiconductor electrode (called a p electrode) 405 are layered on the n-type semiconductor layer 402 and the p-type semiconductor layer 404, respectively. The p electrode 405 has a metal surface, and here the p electrode 405 is encompasses the whole lower surface of the p-type semiconductor layer 404. During driving, light is emitted principally at the surface of the active layer 403.

The LED bare chip 2 having this structure is obtained by successively layering a GaN n-type semiconductor layer and a p-type semiconductor layer on a sapphire substrate with a diameter of approximately 2 inches, according to a CVD method or the like, and then subjecting the formed semiconductor wafer to dicing processing. Instead of sapphire, SiC or GaN may be used for the device substrate 212.

Note that when the LED bare chip 2 is to emit near-ultraviolet light, or blue or green (blue-green) light (light with a relatively short wavelength), it is possible to provide a light emitting layer on the sapphire device substrate 401. Since near-ultraviolet light, and blue or green light pass thorough the sapphire device substrate 401, the light emitting layer may be provided either on the upper surface or the lower surface of the device substrate 401.

In this way, each LED bare chip 2 has a structure in which semiconductor layers 402 and 403 are disposed on the lower surface of the device substrate 401. These semiconductor layers 402 and 403 are used to flip chip (FC) mount the p electrode 405 and the n electrode 406 of the LED bare chip 2 by gold bumps G1, G2, G3 in the aperture in the optical reflection plate 301 with respect to the patterns 201A and 201B in the upper wiring 200 on the surface of the insulation layer 10b. The mounting of the LED bare chip 2 is described in detail later.

Note that although the gold bump G3 is shown in FIG. 4 as being larger than the other gold bumps G1 and G2, this is because the gold bump 3 is shown as being taller in the thickness direction of the LED bare chip 2 semiconductor layers in order to ease comprehension or the structure of the LED bare chip 2. In reality, the gold bumps G1, G2 and G3 differ by no more than several tens of nm in the thickness direction. Furthermore, although the gold bumps G1, G2 and G3 are shown as being substantially circular, in reality they are not necessary perfectly circular, but may be elliptical, for example.

Performing flip chip mounting as described eliminates the need, which exits in conventional shell-type LED devices and the like, to provide wires for power supply in the LED devices, and therefore eliminates the need for areas for wire bonding. This enables the interval between each adjacent pair of LED bare chips 2 to be made narrower, and the LED chips 2 to be mounted with higher density. An advantage of such high-density mounting is that it enables adjustment of colors in display in which multiple LED bare chips 2 (or bare chips) of differing colors are used. Furthermore, since wires are unnecessary, the problem of the wires blocking light during driving is fundamentally solved.

Silicone resin or epoxy resin is placed in the aperture so as to encapsulate the LED bare chip 2 and overflow slightly from the aperture, and is molded into a resin lens 302 having a predetermined shape such as a convex shape or a semispherical shape. Note that phosphor of a desired color may be dispersed in the resin lens 302.

Such a structure of the LED device 300 and its surrounds is the same for each of the 64 LED to 300 in the LED light source unit 30.

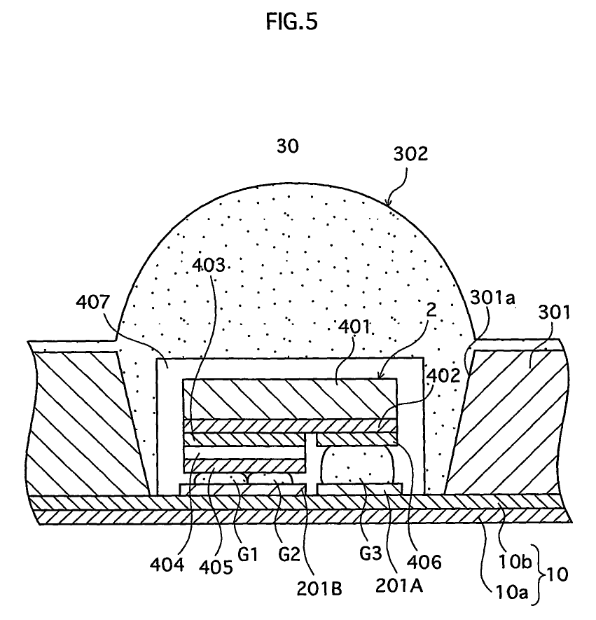

FIG. 5 shows an example of a structure in which phosphor 407 is disposed so as to encapsulate the LED bare chip 2, and the resin lens 302 is formed so as to cover the optical reflecting plate 301. The LED bare chip of the present invention may have this structure.

1.4 Mounting of the LED Bare Chip

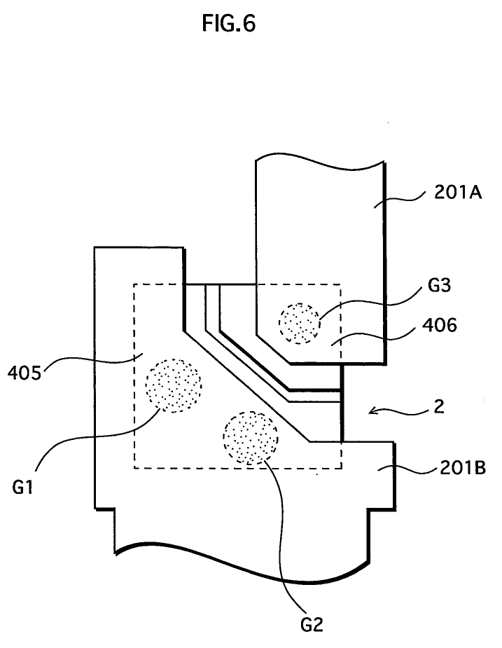

FIG. 6 is a schematic drawing of the LED bare chip 2 as seen from underneath, for describing the junction area in more detail.

As shown in FIG. 6, in the first embodiment, the flip chip mounting (specifically, the n electrode 406 is joined to the upper layer wiring pattern 201A with the one gold bump G3, and the p electrode 405 is joined to the upper wiring 201B with the two gold bumps G1 and G2, using gold-gold bonding) is performed specifically by placing the gold bumps G1, G2 and G3 on the upper layer wiring patterns 201A and 201B, placing the LED bare chip thereon, and applying ultrasonic waves.

Here, as a characteristic of the first embodiment, the total area of the gold bumps G1 and G2 provided with respect to the p electrode 405 between the p electrode 405 whose surface is metal and the mounting pattern 201B is set so as to be no less than 20% of the area of the p electrode 405 that is substantially equal in area to each of the p-type semiconductor layer 404 and the active layer 403. Note that grounds for 20% of the area of the p electrode 405 are described later. In order to achieve this area ratio, the spot diameter of each of the gold bumps G1 and G2 is at least 100 μm. The diameter was set in this way as a result of the inventors investigating heat-dissipation design of the LED card 1, and discovering that if the respective spot diameters of the gold bumps G1 and G2 are at least 100 μm, when the LED card 1 is driven with a maximum current of 50 mA, thermal resistance of the substrate 10 (hereinafter called “substrate 10 thermal resistance”), specifically thermal resistance in the distance corresponding to the “Junction to Package” of the LED bare chips 2 (thickness direction from the active layer 403 of the LED bare chip 2 to the back surface of the metal layer 10a), can be suppressed so as to be no greater than 3.0° C./W. Note that in the present invention, thermal resistance does not denote a value relating to individual LED bare chips, but denotes a value relating to all bare chips when the LED card 1 is driven with all input power. In the present embodiment, thermal resistance is the thermal resistance relating to all input power that drives the chips in 64 places as shown in FIG. 1. In other words, the present invention can be applied even when the embodiment differs from the present embodiment is aspects such as LED chip size, LED chip count, and LED chip shape. In this way, in the first embodiment, by setting the substrate 10 thermal resistance to be no greater than 3.0° C./W by setting the diameters of the gold bumps G1 and G2, when heat dissipating means (heatsink) has been thermally attached to the metal layer 10a of the substrate 10, the temperature (junction temperature) of the LED bare chips 2 during driving is kept to 80° C. or lower.

Note that a number of examples can be given of a structure in which the metal layer 10a of the substrate 10 and the heat dissipating means are provided in close thermal contact. For example, other structures besides one in which the metal layer 10a and the heat dissipating means are physically in direct contact with each other, include one in which the metal layer 10a and the heat dissipating means are physically in direct contact with each other via heat conducting means such as a silicone heat dissipating sheet, silicone rubber, silicone grease, or a heat pipe. Another example is a structure in which the metal layer 10a and the heat dissipating means are provided with a set distance therebetween, and thus without directly contacting each other, via such a heat conducting means. In the present invention, a structure that achieves “close thermal contact” may include the described structures, and is defined as a structure that achieves an effect of dissipating heat from the metal layer 10a of the substrate 10 via the heat dissipating means.

That is to say, conventionally, bumps in flip chip mounting are simply used as connection means between the mounted devices and the wiring. However, in fabricating the LED card 1, the present inventors focused on heat dissipating properties of gold bumps in relation to direct high-density mounting of the LED bare chips 2 on a highly heat dissipating substrate using flip chip mounting. In this way, the LED card 1 is designed to reduce thermal resistance of the substrate 10 during driving. In other words, the inventors have discovered the relationship between the gold bump junction area and the LED bare chip junction temperature in direct mounting of LED bare chips on a highly heat dissipating substrate.

1.5 Effects During Driving

The LED card 1 having the stated structure is mounted in a socket or a connector for usage. At this time the power supply terminals 20a to 20h contact the external terminals provided on the socket or the connector. Furthermore, a heatsink (not illustrated) is mounted on the back surface of the LED card 1 (the surface of the metal layer 10a) so as to be in close contact thermally therewith. It is preferable that the thermal resistance of the heatsink be as low as possible.

If a predetermined power is supplied to the LED card 1 in this state, power is supplied to the bare chips 2 of the LED light source unit 30. This causes the LED bare chips 2 to emit light primarily in the active layer 403. The light is reflected by the cone-shaped reflective surface 301a in the aperture 31 of the aluminium optical reflecting plate 301, and effectively extracted from the from the front surface. The light is further converged by the resin lens 302, and used as a lighting source having a sufficient light output of 1201 m.

Furthermore, at this time heat generated in the LED bare chips 2 is dissipated outside, principally through the substrate 10 via the highly heat conductive metal layer 10a.

Here, in the first embodiment the diameter of the gold bumps G1 and G2 in the p electrode 405 is set so as to be no less than 100 μm, and the total area (junction area) of the gold bumps G1 and G2 is set so as to be no less than 20% of the area of the p-type semiconductor layer 404 that opposes the insulation layer 10b via the p electrode 405. In detail, if the bare chip has a 0.32 mm square, the area of the p-type semiconductor layer 404 is expressed as 0.32 (mm)*0.32 (mm)*75(%)=0.0768(mm²). Therefore, when the bump diameter is 100 μm and two bumps are provided, the junction area is 0.0157 mm², and the bumps occupy approximately 20% of the area of the p-type semiconductor layer 404. According to such settings, the thermal resistance between surface of the active layer 403 and the metal layer 10a (the substrate 10 thermal resistance), which corresponds to the junction to package of the LED bare chip 2, is kept to 3.0° C./W or below.

By keeping the thermal resistance of the substrate 10 to no greater than 3.0° C./W in this way, the temperature of the LED bare chips 2 during driving time of the LED card 1 of the present embodiment is suppressed to be no more than 80° C., and an effect of suppressing excessive heat generation in the LED bare chips 2 is achieved. Generally it is undesirable for the temperature of LED bare chips to exceed 80° C. because such high temperature causes deterioration in performance of the LED bare chips and reduction of luminous efficiency (grounds for this temperature are described in detail later). However, since the temperature of the LED bare chips 2 is suppressed to be no greater than 80° C. in the first embodiment, the LED bare chips 2 can be driven in a desirable, stable manner without the temperature reaching a high temperature of over 80° C.

Furthermore, in the first embodiment, the thermal resistance of the substrate 10 can be adjusted according to the area of the bumps (gold bumps G1 and G2) in flip chip mounting, and therefore the LED card 1 has an advantage of being able to be manufactured relatively simply using a conventional method.

Note that although an example using two bumps (gold bumps G1 and G2) is given in the first embodiment, the number of bumps may be three or more. In such a case, if three bumps having respective diameters of 80 μm are provided, the junction area will be 0.015072 m², and if four bumps having respective diameters of 70 m are provided, the junction area will be 0.015386 mm². In both cases, the bumps will be approximately the same in area as the metal p-electrode 405 and the p-type semiconductor layer 404, and will occupy approximately 20% of the area of the active layer 403.

Note that it is even more preferable for the junction area to occupy 30% or more of the area of the active layer 403 that has substantially the same area as the metal p electrode 405 and the p-type semiconductor layer 404. Furthermore, a material other than metal may be used for the bumps, but metal is preferable in terms of heat conductivity.

Furthermore, the same effect can be obtained if the LED bare chips have a 0.32 mm square by making the junction area at least 20% with respect to the metal p electrode having substantially the same area as the p-type semiconductor layer and the active layer. In addition, if the bumps area positioned separate from each other so that the junction area is dispersed over the surface of the p electrode, effects can be obtained of spreading heat throughout the p electrode and dissipating heat favorably from the active layer of the LED bare chip.

Bumps (solder bumps or gold) only, or the bumps together with another metal material (for example, a junction-use adhesive that includes metal particles) may be used to connect the LED bare chips to the wiring side. Alternatively, an alloy connector or a solder connector, of which gold/tin is representative, may be used to connect the LED bare chips to the wiring side. However, the inventors found through experiments that it is preferable to use gold bumps in performing conventional flip chip mounting processing because they contribute effectively to setting the thermal resistance, as well as high mounting efficiency, mounting junction reliability, and stress easing.

Furthermore, it is not necessary to have a structure that uses spot-shaped bumps. As one alternative structure, the junction may be formed by a junction area that covers the whole p electrode 405 (in other words, an area ratio of 100% with respect to the metal p electrode being substantially equivalent in area to the p-type conductive layer and the active layer).

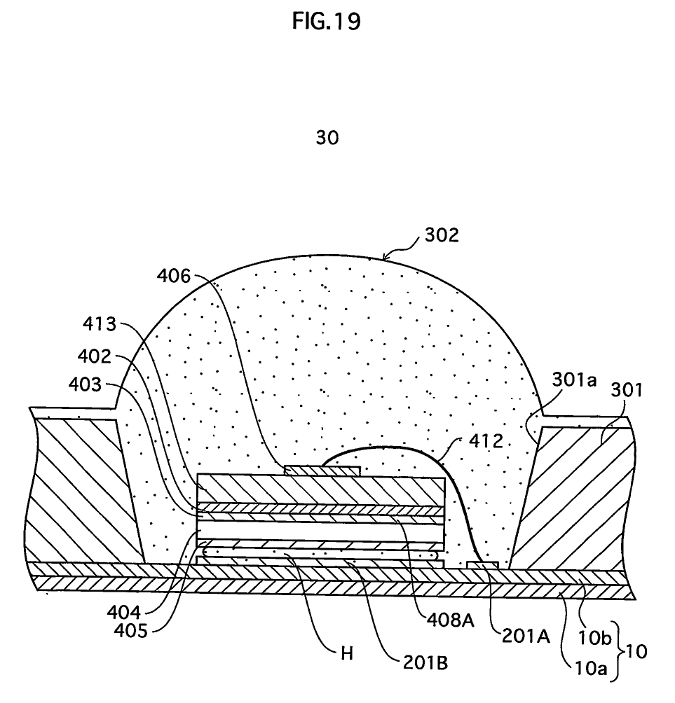

FIG. 19 shows an example of an alternative embodiment of a solder junction in which a light emitting layer is provided on the lower side of the LED bare chip in the same way as a flip chip.

In FIG. 19, an LED bare chip has a structure in which the GaN second semiconductor layer (n-type semiconductor layer) 402, the active layer 403, and the first semiconductor layer (p-type semiconductor layer) 404 are layered downward in the stated order on the lower surface of a device substrate 413 made from SiC, and, in addition, the n electrode 406 is provided on the SiC element substrate 413, and the p-type electrode 405 is provided on the p-type semiconductor layer 404. Here, gold-tin alloy is one example of the material that may be used for the electrodes 405 and 406. During driving, light is emitted principally in the active layer 403.

A light emitting layer provided in this way on the lower side of the LED bare chip allows heat to be dissipated highly effectively.

Furthermore, a favorable heat dissipation effect can also be obtained with a solder junction.

Note that another type of conductive substrate, such as a GaN substrate, may be used for the element substrate of the LED bare chip.

1-6. Grounds for the Numerical Range Specified in the Present Invention

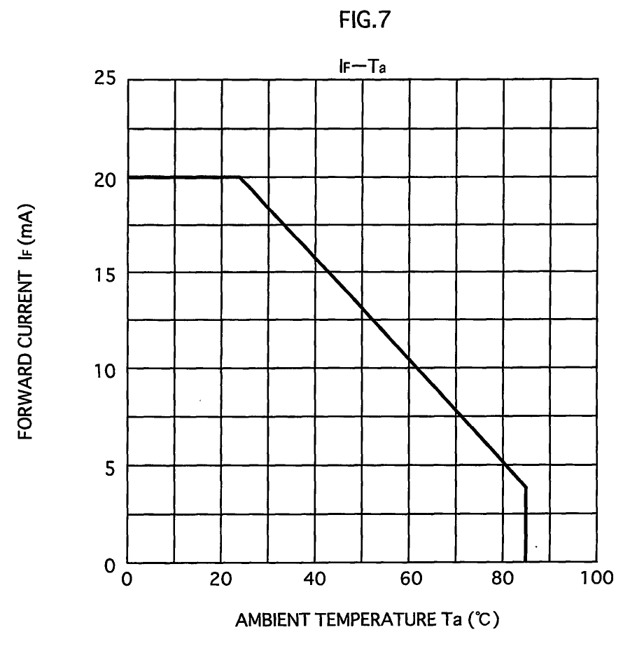

General thermal properties of the LED bare chips are disclosed, for example, in the graph show in FIG. 7 which shows ambient temperature and forward current properties of the LED bare chips (Panasonic DATA BOOK 2000 “Hikari Handotai Soshi Kashi Hakko Diode Unit Shohinhen” (“Optical Semiconductor Devices, Visible Light Emitting Diodes, Unit Products”)).

The graph in FIG. 7 shows the amount of forward current that is appliable in a general LED bare chip when an ambient temperature Ta is increased. A rise in the ambient temperature is accompanied by a rise in the temperature of the LED bare chip. As shown by the graph, when the ambient temperature reaches 80° C. to 85° C., the LED generates excessive heat, and deterioration of the device advances extremely. For this reason, 80° C. is thought to be the maximum heat generating temperature at which sufficient power is supplyable to LED bare chips. Consequently, if the temperature of the LED bare chip exceeds 80° C., this temperature rise becomes a restriction, and sufficient power is no longer able to be supplied to the LED bare chip. Furthermore, if the temperature exceeds 80° C., the sealing resin of the LED bare chip begins to exhibit considerable heat deterioration. For this reason, in addition to incurring a reduction in luminous efficiency, the LED bare chip itself is also thought deteriorate due to the heat, as described above.

Taking the described thermal properties into account, the present inventors performed experiments to measure the temperature in LED bare chips when the power input to the LED bare chips was set at 40 mA and the resistance of the substrate was varied. When a large current that exceeds the current density 260 mA/mm² of a general size LED bare chip is applied and a large luminous flux is to be obtained, the luminosity amount reaches saturation due to the carrier overflow in the area in which large current whose density exceeds approximately 660 mA/mm², even if the temperature of the LED bare chips is maintained close to room temperature, and markedly increased defects occur in the epilayer of devices during operation. This causes a reduction in lifespan.

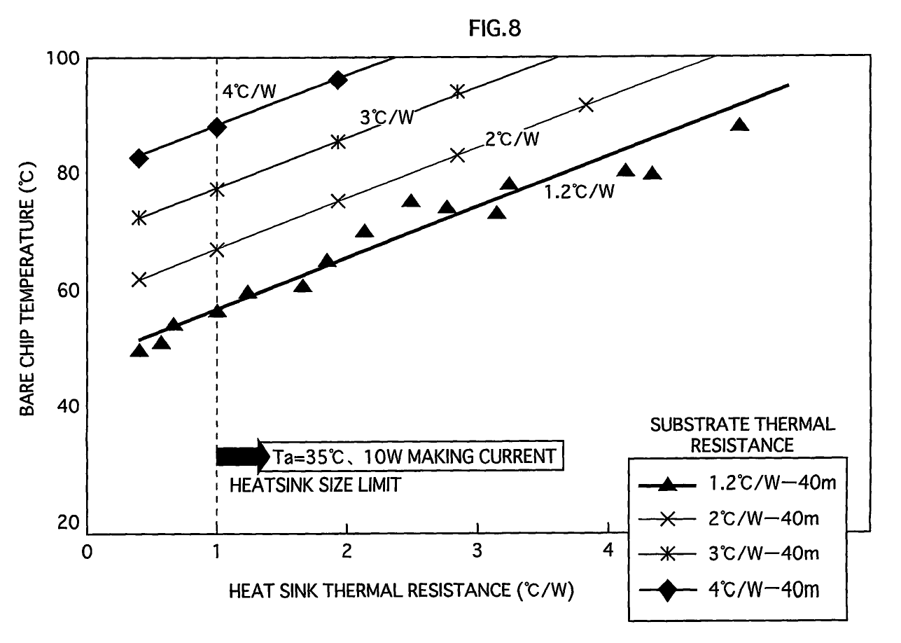

The experiment results are shown in the graph in FIG. 8, which indicates the relationship between bare chip temperature and heats ink thermal resistance. In this experiment, a heatsink was provided so as to be in close thermal contact with the metal layer of the LED card, and the thermal resistance of the heatsink was varied.

As can be seen from the graph in FIG. 8, when the LED bare chips are driven under the conditions of an ambient temperature prior to driving of 35° C. (this temperature being close to body temperature and though of as the value of the upper limit of room temperature in a living space), a forward current of 40 mA, and a making current of 10 W, and when the thermal resistance of the heatsink is extremely low (specifically, 1° C./W), if the thermal resistance of the substrate is 3° C./W or less, the LED bare chip temperature can be kept at 80C or lower.

Consequently, when actually driving the LED card 1 using the heat dissipating effect of the heatsink, stable driving, without causing excessive rise in the temperature of the LED bare chips, can be said to be possible if the thermal resistance of the substrate is 3° C./W or lower.

The reason for using 1° C./W as a reference for the heatsink thermal resistance as in FIG. 8 when measuring the thermal resistance of the substrate is as follows.

Specifically, if thermal resistance of the heat dissipating means (heatsink) is decreased, the volume (enveloping volume) thereof increases. It is preferable for the thermal resistance of the heat dissipating means to be low, in other words, for the enveloping volume of the heat dissipating means to be high, because this increases heat dissipating performance. However, in reality, there is a limit to the size of the heatsink when the LED card 1 of the present invention is incorporated into an LED lighting apparatus as a light source.

The size of room-use lighting sources currently on the market can be used as a reference for a specific size of a usable heatsink. For example, in the “Parukku Ball G-Type Series” which is relatively-large in size among bulb-type fluorescent lamps by Matsushita Electrical Industrial Co., Ltd., an example of the size of the heatsink is an outer diameter of 90 mm, a length of 130 mm, and a volume of approximately 830 cm³ when measured as the volume of an approximately cylindrical shape.

Here, Table 1 shows data that includes the relationship between the enveloping volume of the heatsink and the heatsink thermal resistance. In Table 1, “Heatsink No.” refers to a number given to at sink prepared as a sample. The heatsink numbers were assigned at the larger the number, the lower the enveloping volume.

TABLE 1
Relationship Between Heatsink and Junction Temperature

(Ambient Temperature: Ta = 25° C.)

| | Thermal | | | | | |
|---|---|---|---|---|---|---|
| | Resistance | Enveloping | Junction Temperature (° C.) | | | |
| Heatsink | (10 W) | Volume | 20 | 30 | 40 | 50 |
| No. | ° C./W | cm³ | mA | mA | mA | mA |
| 1 | 0.38 | 4464 | 34.8 | 38.7 | 41.7 | 44.5 |
| 2 | 0.56 | 2322 | 35.2 | 39.0 | 43.3 | 46.8 |
| 3 | 0.65 | 1108.8 | 35.8 | 41.8 | 46.7 | 50.3 |
| 4 | 1.0 | 816 | 36.5 | 42.8 | 48.3 | 52.8 |
| 5 | 1.24 | 571.2 | 38.5 | 44.4 | 51.5 | 55.0 |
| 6 | 1.7 | 400 | 39.5 | 46.1 | 52.3 | 57.7 |
| 7 | 1.9 | 280 | 41.2 | 48.7 | 56.5 | 62.3 |
| 8 | 2.2 | 208 | 43.2 | 52.9 | 61.4 | 69.7 |
| 9 | 2.6 | 145.6 | 46.1 | 57.6 | 66.8 | 74.2 |
| 10 | 2.9 | 144.06 | 44.1 | 56.0 | 65.6 | 73.8 |
| 11 | 3.3 | 104 | 47.2 | 56.8 | 64.5 | 74.8 |
| 12 | 3.4 | 108.78 | 46.8 | 59.3 | 69.0 | 78.0 |
| 13 | 3.9 | 100 | 47.6 | 60.3 | 69.5 | 79.5 |
| 14 | 4.3 | 73.5 | 47.2 | 64.4 | 70.8 | 81.3 |
| 15 | 4.5 | 59.5 | 53.2 | 57.5 | 69.8 | 82.5 |
| 16 | 5.2 | 52.5 | 51.3 | 69.0 | 78.5 | 86.4 |
| 17 | 5.6 | 42.5 | 52.6 | 68.6 | 92.0 | |

Junction Temperature (° C.)

As can be seen from the data for heatsink No. 4 in Table 1, when the enveloping volume is 816 cm³, the thermal resistance is 1.0° C./W. The thermal resistance can be lowered if the enveloping volume is increased, however, heatsink No. 4 is suitable in terms of size because its volume is approximately 830 cm³ when considered as a cylindrical shape, and therefore can be incorporated in a lighting apparatus in reality. Consequently, a heatsink having the size of No. 4 and the thermal resistance of 1.0° C./W is thought to be appropriate as a reference for a realistic heatsink. For this reason, 1.0° C./W is used as a reference for heatsink thermal resistance in FIG. 8.

Note that when the LED bare chips 2 in the LED card 1 of the present invention are formed in a square shape with a 0.32 mm square, the area of the active layer 403 is substantially the same as the area of the p-type semiconductor layer 404, and, as one example, occupies 75% of the area of the LED bare chip 2. Therefore, the area of the active layer can be expressed by an expression 0.32 (mm)*0.32 (mm)*75(%)=0.0768 (m²). Based on this expression, the current density in the active layer 403 when forward currents of 20 mA, 30 mA, 40 mA, and 50 mA, respectively, are applied to the LED bare chips 2 during driving will be 260 mA/mm², 390 mA/mm², 521 mA/mm², and 651 mA/mm². Here, particularly when applying a forward current of 50 mA to the LED bare chips 2, the temperature of the LED bare chips 2 may exceed 80C if a heatsink having an enveloping (external dimensions)volume of 100 cm³ and thermal resistance of approximately 4.0° C./W is used as the heat dissipating means provided in close thermal contact with the metal layer 10a of the LED card 1.

Furthermore, sufficient luminous flux for use as a lamp cannot be obtained if the forward current is below 20 mA (a current density of 250 mA/mm² in the active layer 403).

For these reasons, the appropriate range for the current density in the active layer 403 of the LED bare chips 2 of the present invention is thought to be 250 mm² to 660 mA/mm².

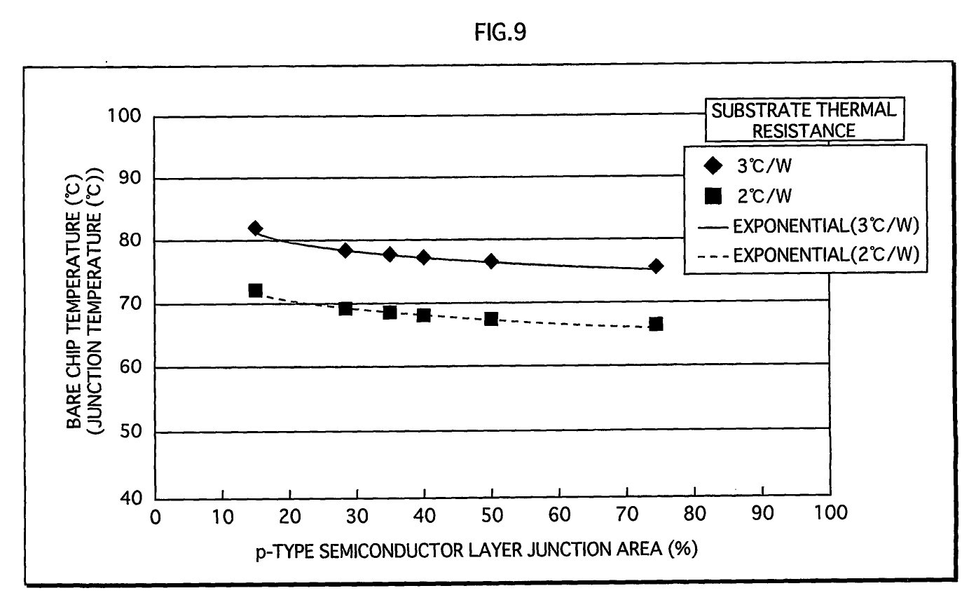

FIG. 9 is a graph showing the relationship between junction area of the p-type semiconductor layer of the LED bare chip (specifically, the junction area (the spot area of Gland G2) occupying the p electrode area having the same area as the p-type semiconductor layer) and the junction temperature Tj, under a set condition of the substrate thermal resistance being 3° C./W or 2° C./W.

As is clear from FIG. 9, the junction area and the junction temperature Tj are inversely proportionate, and in order to keep the junction temperature to 80° C. or below, it is necessary for the junction area to occupy at least 20% of the p-type semiconductor layer when the thermal resistance is 3° C./W. This data forms the grounds for setting the total area of the gold bumps G1 and G2 (junction area) to be at least 20% of the area of the p-type semiconductor layer 404 in the first embodiment.

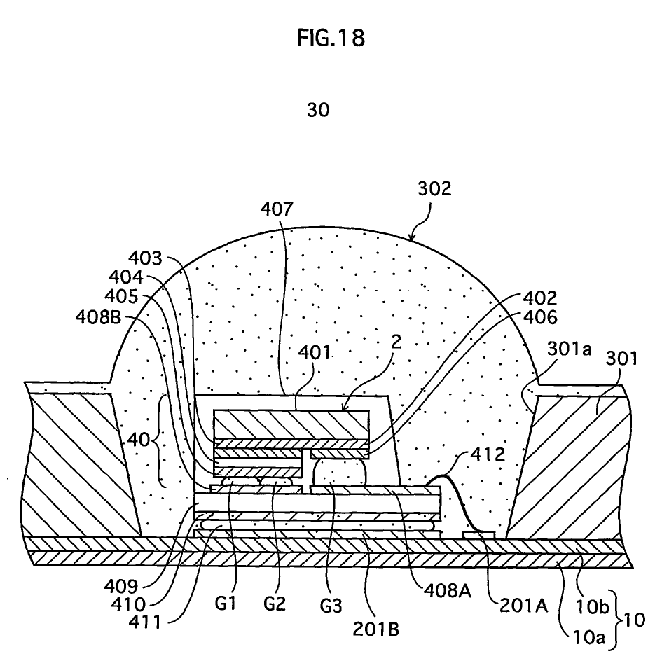

Note that although the LED bare chips are mounted directly on the first main surface of the mounting substrate by flip chip mounting in FIG. 5, the LED bare chips may be mounted indirectly on the first main surface of the mounting substrate by a submounting method. An example of this is shown in FIG. 18. In the present invention, the LED bare chips may be mounted indirectly on the mounting substrate in this manner.

Specifically, FIG. 18 shows an example of a cross section of an LED module in which the LED devices have been mounted on the mounting substrate indirectly. The following describes this in detail.

An LED module 30 in FIG. 18 is an LED mounting module that has the same structure as that shown in FIG. 5. The LED mounting module includes the substrate 10 and a reflective plate 301. An LED bare chip 401 is mounted indirectly as a submount 40 on an LED mounting position of the LED mounting module. Note that the LED module 30 includes a lens plate 302 that is identical to that in FIG. 5.

The submount 40 is composed of, for example, a silicon substrate 409, the LED bare chip 401 which is mounted on the top surface of the silicon substrate 409, and phosphor 407 that envelopes the LED bare chip 401. Here, the LED bare chip 401 is mounted on the silicon substrate 409 via gold bumps G1, G2, and G3.

Note that a first electrode 408B, which is electrically connected from the p electrode 405 of the LED bare chip 401, is formed on the top surface of the silicon substrate 409. Furthermore, an electrode 410, which is electrically connected from the first electrode 408B, is formed on the bottom surface of the silicon substrate 409. A second electrode 408A, which is electrically connected to an n electrode 406 of the LED bare chip 401, is also formed on the top surface of the silicon substrate 409.

In the present example, aluminium is used as the electrode material, and the junction is a gold-aluminium junction. However, gold, tin, or alloys thereof may be used, and selected so that the junction is a gold-gold junction or a gold-tin junction.

The submount 40 is mounted to the LED mounting-use module using electrically conductive paste (silver paste) 411. The submount 40 and the substrate 10 are electrically connected by the electrode 410 on the bottom surface of the silicon substrate 409 being connected via the silver paste 411 to the wiring patterns 201B formed on the substrate 10, and the second electrode 408A on the top surface of the silicon substrate 409 being connected via a wire 412 to the wiring pattern 201A of the substrate 10.

Metal powder and resin are used for the electrically conductive paste. Other than silver, the metal powder may be one or more types selected from the group consisting of copper, nickel, palladium, and tin, or an alloy of one or more of the types.

When the LED bare chip 401 is mounted indirectly by submounting, the submount 40 that includes the phosphor 407 can be formed in advance, and therefore, for example, it is possible to check whether the LED device that has been mounted on the silicon substrate illuminates normally. Consequently, the submount can be mounted on the LED mounting module after being checked, and effects such as increased yield in manufacturing can be obtained.

<Second Embodiment>

2-1. Structure of the LED Lighting Apparatus (Bulb-Type Lamp)

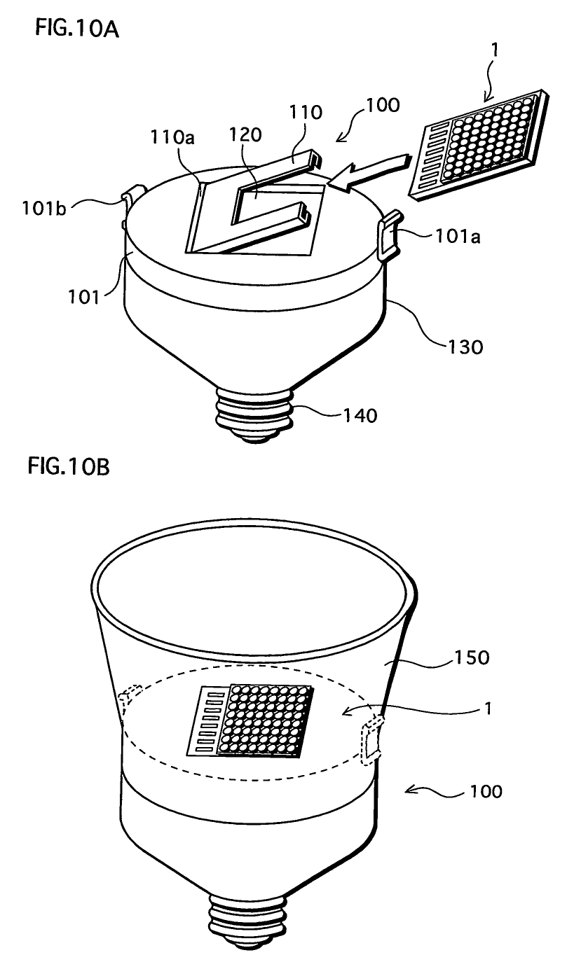

FIG. 10A shows the structure of an LED lighting apparatus of the second embodiment. An LED lighting apparatus 100 shown in the drawing can be used as a general bulb-type lamp, and uses the LED card 1 having the structure of the first embodiment shown in FIG. 1 as the light source.

As shown in the FIG. 10A, the LED lighting apparatus is roughly composed of a disc-shaped LED mounting unit 101, a main body 130, and a screw-type terminal 140.

A card socket 110 which removably holds the LED card 1 described in the first embodiment is provided on the main surface of the LED mounting unit 101. The card socket 110 is connected to a main surface side of the LED 110 by a hinge 110a, and is normally stored parallel to the main surface of the LED mounting unit 101, embedded therein. A user is able to remove the LED card 1 by raising the card socket 100. Note that terminals that are electrically connectable with the power terminals 20a to 20h of the LED card 1 are provided in the card socket 110. These terminals supply the LED card 1 appropriately with power via a commonly known lighting circuit (not illustrated) housed in the main body 130.

The card slot 110 can be fabricated, for example, from a material such as aluminium or cupronickel, which has superior heat discharge properties. Claws 101a and 101b provided of a side surface of the LED mounting unit 101 can be used to attach a lamp shade 150.

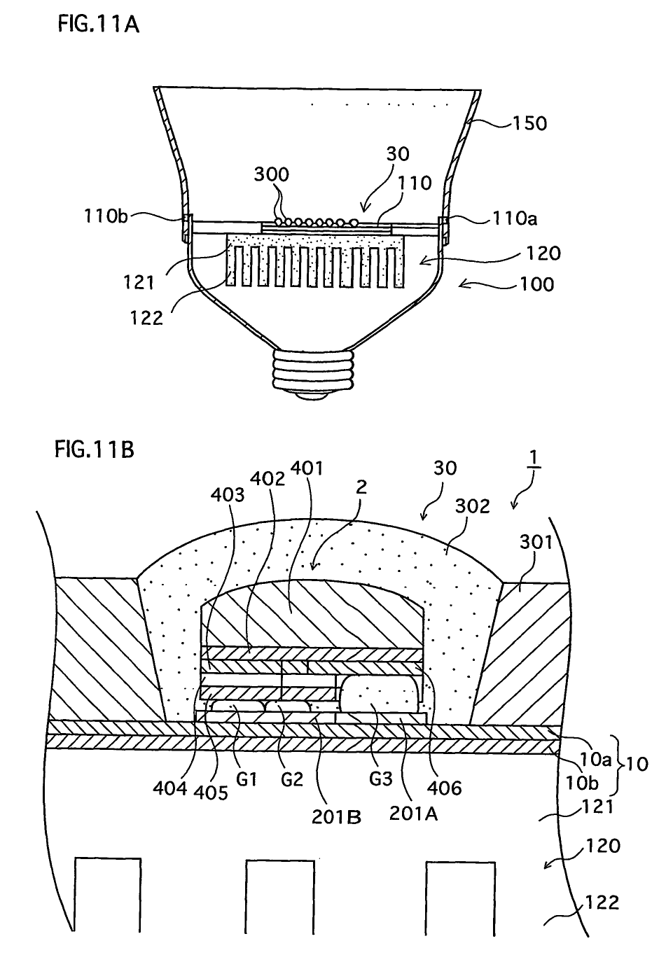

As shown in the cross sectional drawing of the lighting apparatus in FIG. 11, the LED mounting unit 101 is provided internally with a base 121 that is parallel to the main surface of the LED mounting unit 101 and is directly below the card socket 110, and a heatsink 120 that is a heat dissipating means. The heatsink 120 has a plurality of fins 122 that extend toward the inside of the main body 130, and is fabricated from a material that has superior heat conducting properties such as copper or aluminium. The base 121 of the heatsink 120 is disposed so that the surface thereof is in close thermal contact with the metal layer 10b of the LED card 1 mounted in the card socket 110.

Note that the material used for the heatsink may be one or more types selected from the group consisting of Al, Cu, W, Mo, Si, AlN, and SiC.

A characteristic of the second embodiment is that the heatsink 120 has an enveloping volume of at least 100 cm³, and its heat dissipating ability is a thermal resistance of at least 4.0° C./W.

2-2. Effects of the Heatsink of the Present Invention

According to the lighting apparatus 100 having the stated structure, the screw-type terminal is mounted in a commonly known socket at the time of use. During driving, the LED light emitting unit 30 emits light at a luminous output of 1201 m, according to power of a maximum voltage of 120 V to the LED card 1.

At this time, heat generated in the LED card 1 is favorably dissipated from the substrate 10 by the heatsink 120 provided in close thermal contact with the metal layer 10a of the LED card 1. In the second embodiment, since the heat dissipating ability of the heatsink 120 is a thermal resistance of at least 4.0° C./W, the heat generated in the bare chips 2 is effectively dissipated from the p electrode 405 through the metal layer 10a to the heatsink 120 side, and the temperature emitted by the LED bare chips 2 is kept to 80C or lower. As a result, thermal deterioration of the LED bare chips 2 can be prevented, superior luminous efficiency can be achieved, and the lighting apparatus 100 can be used as a favorable lighting apparatus.

2-3. Relationship Between LED Bare Chip Temperature and Heatsink Characteristics

The following describes information about the relationship between LED bare chip temperature in the LED card 1 and heatsink characteristics, obtained by the inventors according to experiments. Note that LED chip temperature is measured as the junction temperature at the p electrode.

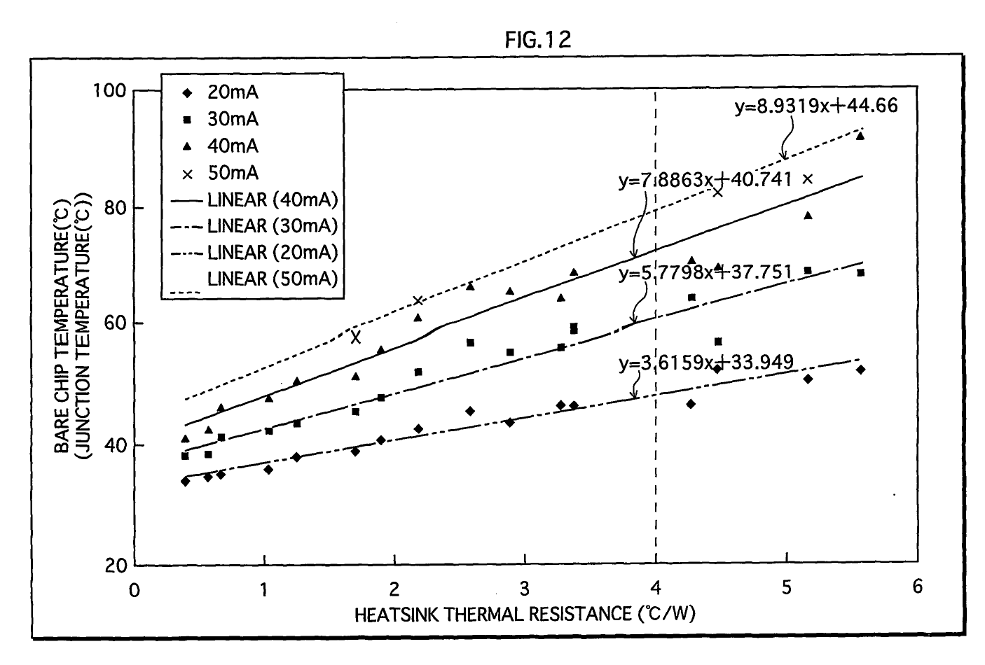

FIG. 12 is a graph showing the relationship between bare chip temperature and heatsink resistance. The graph shows the respective effects of thermal resistance of the heatsink on the bare chip temperature when the LED bare chip are driven with maximum currents of 20 mA (5 W), 30 mA (6 W), 40 mA (9 W), and 50 mA (11 W). The lines in the graph are drawn according to the respective relation expressions indicated in the graph with respect to the lines.

The heat generated in the LED card during driving depends on the forward current in the making power and the thermal resistance of the heatsink used. As described earlier, it is important to keep the driving temperature of the LED bare chips to 80° C. or below for reasons of thermal deterioration and maintaining luminous efficiency. Consequently, it is necessary to select a heatsink for use in the LED lighting apparatus of the present invention that has the ability to keep heat emitted by the LED bare chips to 80° C. or below.

Referring at the graph with such a condition in mind, it can be seen that when driving the LED bare chips with a maximum current of 50 mA, the LED bare chip temperature cannot be kept to 80° C. or lower if the heat sink thermal resistance is not sufficiently less than 5.0° C./W. Consequently, it is thought that choosing a heatsink with a thermal resistance of 4.0° C./W will enable the LED bare chip temperature during driving to be kept to substantially 80° C. or lower.

Since a making power with a maximum current of 50 mA is generally thought to be the upper limit for making power for driving LED bare chips in an LED card, it is thought that the LED bare chip temperature can be kept to 80° C. or below if the thermal resistance of the heatsink is 4.0° C./W or lower. These grounds form the basis for the use of a heatsink with a thermal resistance of 4.0° C./W or lower in the present invention.

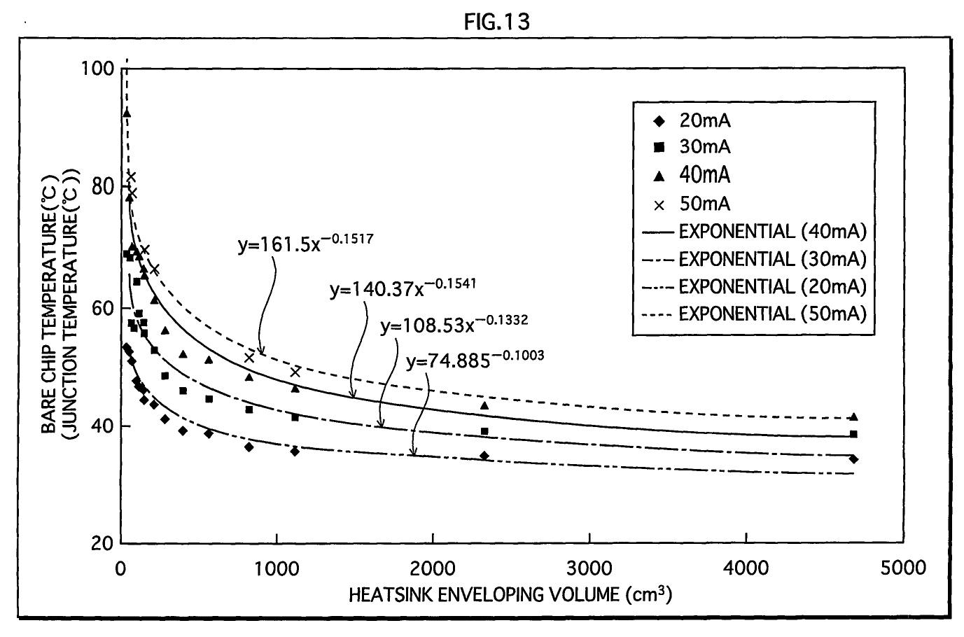

FIG. 13 is a graph showing the relationship between bare chip temperature and heatsink enveloping volume. This graph also indicates results for when the LED bare chips were driven with maximum currents of 20 mA, 30 mA, 40 mA, and 50 mA, and shows the effect of heatsink enveloping volume on bare chip temperature. The lines in the graph are drawn according to the respective relation expressions indicated in the graph with respect to the lines.

The graph shows that the LED bare chip temperature can be kept to 80° C. or below if the heat sink enveloping volume is 100 cm³ or greater. From this is can be concluded that a heatsink having an enveloping volume of 100 cm³ is preferable for use in the present invention. Taking into consideration the heatsink thermal resistance shown in FIG. 8 and the upper limit of the enveloping volume thereof, thermal resistance properties of no less than 1.0° C./W and no greater than 4.0° C./W can obtained if a heatsink having an enveloping volume of at least 100 cm³ and no greater than 820 cm³ is used. This enables heat to be discharged effectively from the LED bare chips.

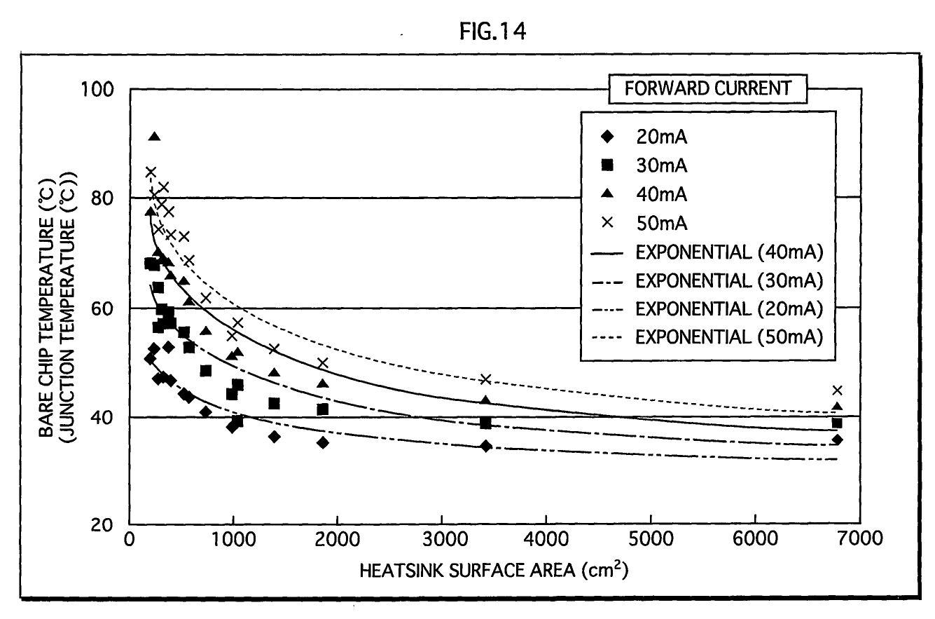

FIG. 14 is a graph showing the relationship between bare chip temperature and heatsink surface area. This graph also indicates results for when the LED bare chips were driven with maximum currents of 20 mA, 30 mA, 40 mA, and 50 mA, and shows the effect of heatsink surface area on bare chip temperature.

The graph shows that the LED bare chip temperature can be kept to substantially 80° C. or below if the heat sink if the area is at least a certain size. From this is can be concluded that a heatsink having a area of at least a certain size is preferable for use in the present invention. Furthermore, if the surface area of the heatsink is sufficiently large, the heat generated in the LED bare chips falls gradually from around 50° C. and saturation occurs. Therefore, an unnecessarily large heatsink is not required in terms of reducing the heat generated in the LED bare chips.

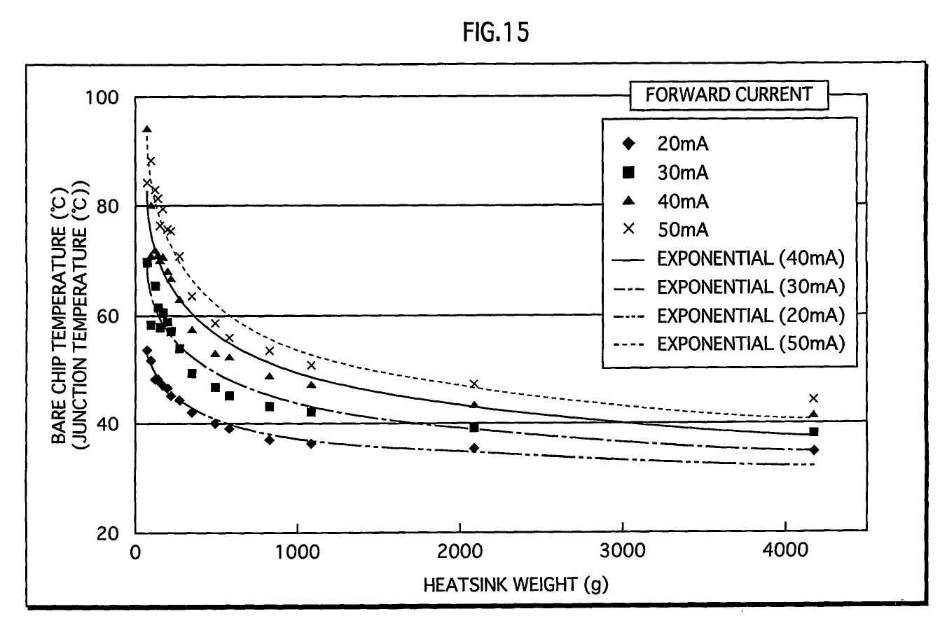

FIG. 15 is a graph showing the relationship between bare chip temperature and heatsink weight. This graph also indicates results for when the LED bare chips were driven with maximum currents of 20 mA, 30 mA, 40 mA, and 50 mA, and shows the effect of heatsink weight on bare chip temperature.

The graph shows that the LED bare chip temperature can be kept to substantially 80° C. or below the weight is at least a certain amount. From this is can be concluded that a heatsink having a weight of at least a certain amount is preferable for use in the present invention. Furthermore, if the area of the weight of the heatsink is sufficiently large, the heat generated in the LED bare chips falls gradually and saturation occurs. Therefore, an unnecessarily heavy heatsink is not required in terms of reducing the heat generated in the LED bare chips.

As described, it is clear that LED bare chip temperature changes due to factors such as heatsink thermal resistance, enveloping volume, area, and weight. This means that the heatsink can be subject to various quantative analytic evaluations according to the stated factors.

2-4. Other LED Lighting Apparatus Structures

The LED lighting apparatus is not limited to the structure described in the second embodiment in which the LED card 1 is removable from the card socket 110. Furthermore, a plurality of LED cards 1 may be used in the LED lighting apparatus.

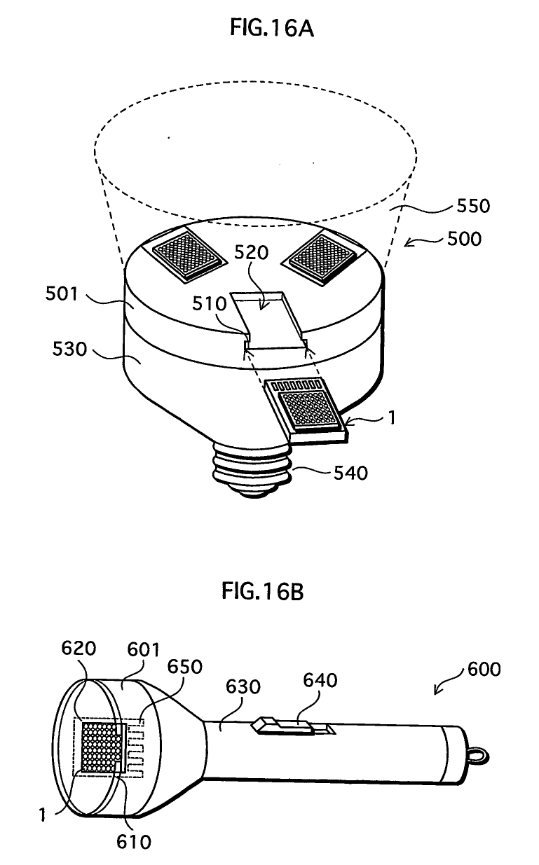

FIGS. 16A and 16B shows variations of the structure of the LED lighting apparatus of the second embodiment.

FIG. 16A shows the structure of a lighting apparatus 500 that is a bulb-type lamp similar to the lighting apparatus 100 of the second embodiment.

An LED mounting unit 501 of the lighting apparatus 500 a has slot unit 510 instead of a card socket that is a separate member as in the second embodiment. The slot unit 410 is provided as a channel in the surface of the disc-shaped LED mounting unit 501, and removably holds one of the LED cards 1. A lamp shade 550 can be provided on the periphery of the LED mounting unit 501. Furthermore, a screw-type terminal 540 that is connectable with a commonly-known external socket is provided at the bottom of the main body 530.

With this structure, an LED card 1 provided on the LED mounting unit 501 is in close thermal contact with a heatsink 520 provided inside the LED mounting unit 501, in a similar manner to the second embodiment. The heatsink 520 has a thermal resistance of 4.0° C./W or lower.

The three LED cards 1 are positioned evenly on the disc-shaped LED mounting unit 501, the extra LED cards 1 meaning that a higher luminous output is achieved that that of the LED lighting apparatus 100 of the second embodiment. This structure achieves substantially the same effects as the second embodiment, with the heat generated in the LED cards 1 being kept to 80° C. or lower.

Furthermore, FIG. 16B shows an example of a structure of a torch-type LED lighting apparatus 600. This LED lighting apparatus 600 is roughly composed of an LED mounting unit 601, a grip unit 630, a switch unit 640, and so on.

In this structure, the LED card 1 is removably mounted in a card slot 610 formed on a surface of the LED mounting unit 601. When the LED card 1 is in a mounted stated, the metal layer 10a of the LED card 1 is in close thermal contact with a heatsink 620 provided in the LED mounting unit 601. The heatsink 620 also has a thermal resistance of 4.0° C./W or lower. A battery or batteries are housed in the grip unit 630 as in a commonly-known torch, and power is supplied to the LED card 1 by the sliding switch unit 640 being operated.

This LED lighting apparatus 600 having a torch-type structure achieves substantially the same effects as the second embodiment, with the heat generated in the LED cards 1 being kept to 80° C. or lower.

2-5. Heatsink Variations

The heatsink used in the present invention is not limited to the heatsinks 120, 520 and 620, which have a plurality of fins on a base, disclosed in the second embodiment and the variations.

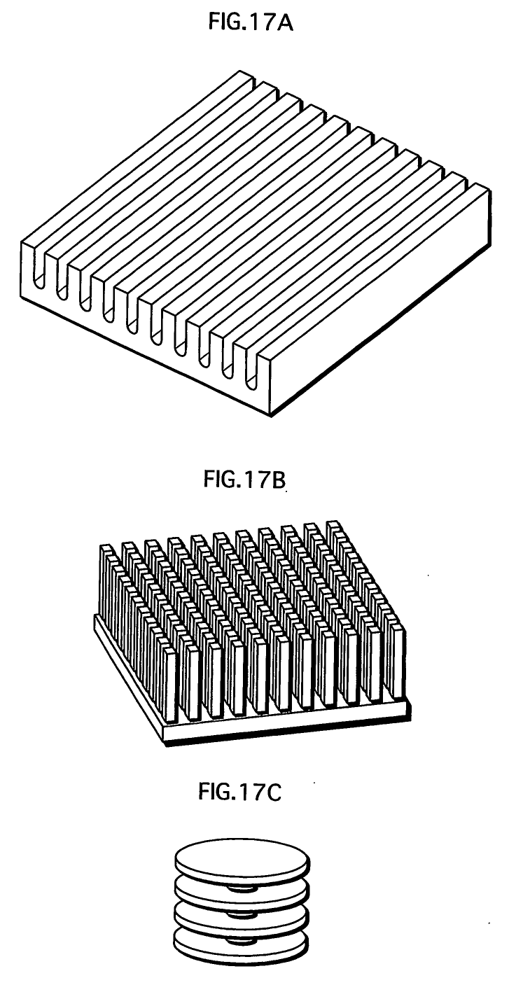

FIGS. 17A, 17B and 17C show other heatsink structures.

FIG. 17A shows the structure of a heatsink that has a plurality of thick ribs provided on a plate-shaped base. This structure is basically the same as the heatsinks 120, 520, and 620 described in the second embodiment and the variations, but the thickness and number of the fins is able to be appropriately adjusted. Adjusting these devices enables, for example, the surface area of the heatsink to be set.

FIG. 17B shows the structure of a heatsink that has a plurality of thin, square-shaped prongs provided on a plate-shaped base. This shape of heatsink is generally used as a heat dissipating means for the CPU of a personal computer, but may be used as the heat dissipating means for the LED card 1 of the present invention.

FIG. 17C shows the structure of a heatsink that has a plurality of disc-shaped bases provided with intervals there between and a column connecting the center of each base. In this structure each base is also a fin. The LED card 1 is put in close thermal contact to the bottom base. This structure is advantageous in that factors such as the thermal resistance, enveloping volume, area, weight, and so on of the heatsink that determine heat dissipating properties can be easily set by increasing the number of bases provided.

Note that other heatsinks, such as one that includes a heat pipe, may be used. Furthermore, the heatsink may be used in combination with a forced cooling device such as a fan, a water-cooling device, a Peltier device, or a self-vaporizing heatsink.

<Other Remarks>

The card-type LED module disclosed in the embodiments may be used as a light source in an apparatus other than an LED lighting apparatus. As one example, the LED module may be used as a light source in a device, such as a display device, that requires highly luminous light emission.

### INDUSTRIAL APPLICABILITY

The present invention may be used in lighting fixtures and lighting apparatuses that require a compact, thin or light-weight light source.

1. An LED lighting source comprising:
a mounting substrate having a wiring pattern on a first main surface thereof; and
a plurality of LED bare chips, each composed of a first semiconductor layer and a second semiconductor layer that have respectively different conductivity, an active layer disposed between the first and second semiconductor layers, and a metal electrode disposed on the first semiconductor layer and being substantially equal in area to the first semiconductor layer, and each LED bare chip being joined to the wiring pattern according to flip chip mounting of the metal electrode to form a junction between the wiring pattern and the metal electrode,
wherein each junction is formed so that an area thereof is at least 20% of the area of the metal electrode, and
thermal resistance from the active layers through to a second main surface of the mounting substrate, which is a back surface thereof, is set to 3.0° C./W or lower.

2. The LED lighting source of claim 1, wherein
at least the metal electrodes disposed on the first semiconductor layers and the wiring pattern are joined according to one of a gold-gold junction, a gold-aluminium junction, and a gold-tin junction.

3. The LED lighting source of claim 1, wherein
each junction between the metal electrodes disposed on the first semiconductor layer of each LED bare chip and the wiring pattern is made up of two or more bumps.

4. The LED lighting source of claim 1, wherein
each junction between the metal electrodes disposed on the first semiconductor layer of each LED bare chip and the wiring pattern is made up of two or more bumps that each have a diameter of at least 100 μm, or three or more bumps that each have a diameter of at least 80 μm.

5. The LED lighting source of claim 1, wherein
current density of the active layer of each LED bare chip during driving is in a range of 250 mA/mm² to 660 mA/mm² inclusive.

6. The LED lighting source of claim 1, wherein
the mounting substrate is composed of an insulation layer and a metal layer, the first main surface on which the wiring pattern is disposed being a main surface of the insulation layer, and the second main surface of the mounting substrate, which is an opposite surface to the surface on which the wiring pattern is disposed, being a surface of the metal layer.

7. The LED lighting source of claim 1, wherein
the mounting substrate includes an insulation layer that is composed of a composite material that includes an inorganic filler and a resin composite.

8. The LED lighting source of claim 1, wherein
the mounting layer includes an insulation layer that is composed of a ceramic material.

9. The LED lighting source of claim 1, wherein
the mounting substrate is composed of a ceramic material.

10. The LED lighting source of claim 9, wherein
the ceramic material includes at least one of AlN, Al₂O₃, and SiO₂.

11. An LED lighting apparatus comprising the LED lighting source of claim 1, wherein
the LED lighting apparatus includes a heats ink that is provided in close thermal contact with the back surface of the mounting substrate, and that has a thermal resistance of no less than 1.0° C./W and no greater than 4.0° C./W.

12. The LED lighting apparatus of claim 11, wherein
the heatsink is composed of at least one material chosen form the group consisting of Al, Cu, W, Mo, Si, AlN, and SiC.

13. An LED lighting apparatus comprising the LED lighting source of claim 1, wherein
the LED lighting apparatus includes a heats ink that is provided in close thermal contact with the back surface of the mounting substrate, and that has an enveloping volume of 100 cm³ to 820 cm³, inclusive.

14. The LED lighting apparatus of claim 13, wherein
the heatsink is composed of at least one material chosen form the group consisting of Al, Cu, W, Mo, Si, AlN, and SiC.

15. An LED lighting apparatus comprising the LED lighting source of claim 1, wherein
the LED bare chips are mounted to the mounting substrate by each LED bare chip being joined with a submount according to flip chip mounting, and each sub-mount being electrically joined with the wiring pattern on the first main surface of the mounting substrate.

16. An LED lighting apparatus comprising the LED lighting source of claim 15, wherein
the submounts and the mounting board are joined by conductive paste.

17. An LED lighting apparatus comprising the LED lighting source of claim 16, wherein
the conductive paste is composed of (i) at least one material selected from the group consisting of silver, copper, nickel, palladium, and tin; or an alloy that includes one of the materials, and (ii) one of the materials mixed with resin.
